(19) United States
(12) Patent Application Publication
(10) Pub. No.: US 2012/0195171 A1
(43) Pub. Date: Aug. 2, 2012

(54) METHOD OF MANUFACTURING PIEZOELECTRIC VIBRATING REED, PIEZOELECTRIC VIBRATING REED, PIEZOELECTRIC VIBRATOR, OSCILLATOR, ELECTRONIC DEVICE, AND RADIO-CONTROLLED TIMEPIECE

(76) Inventor: Daiki Irokawa, Chiba-shi (JP)

(21) Appl. No.: 13/360,417

(22) Filed: Jan. 27, 2012

(30) Foreign Application Priority Data
Jan. 27, 2011 (JP) 2011-015442

(51) Int. Cl. G04C 11/02; H03B 5/32; H01L 41/22; H01L 41/04

(52) U.S. Cl. 368/47; 310/370; 331/158; 216/13

(57) ABSTRACT

In a method of manufacturing a piezoelectric vibrating reed for forming electrodes on a surface of a piezoelectric plate using a photolithography technique, an electrode forming step of forming excitation electrodes includes: an exposure step of exposing a photoresist (mask material); a developing step of immersing the photoresist in a developing solution to selectively remove the photoresist to thereby form a mask pattern; and an etching step of forming the excitation electrodes. An immersing step of immersing a piezoelectric plate on which the photoresist is applied in a first solution that is dissolvable in the developing solution and has lower viscosity than the developing solution is performed between the exposure step and the developing step.

### RELATED APPLICATIONS

This application claims priority under 35 U.S.C. §119 to Japanese Patent Application No. 2011-015442 filed on Jan. 27, 2011, the entire content of which is hereby incorporated by reference.

### BACKGROUND OF THE INVENTION

1. Field of the Invention

The present invention relates to a method of manufacturing a piezoelectric vibrating reed, a piezoelectric vibrating reed manufactured by the manufacturing method, a piezoelectric vibrator, an oscillator, an electronic device, and a radio-controlled timepiece each using the piezoelectric vibrating reed.

2. Description of the Related Art

In recent years, piezoelectric vibrators using crystal or the like are used in mobile phones or mobile information terminals as a time source, a control signal timing source, a reference signal source, and the like. Various piezoelectric vibrators are available as such kinds of piezoelectric vibrators, and a piezoelectric vibrator having a tuning-fork type piezoelectric vibrating reed is also known as one of the piezoelectric vibrators.

For example, a tuning-fork type piezoelectric vibrating reed disclosed in JP-A-2008-98747 includes a base portion and a first vibrating arm and a second vibrating arm (corresponding to the “vibrating arm portions” of the present disclosure) extending from one end portion of the base portion. A first base electrode and a second base electrode (corresponding to the “mount electrodes” of the present disclosure) are formed on the base portion of the crystal vibrating reed, and a first groove electrode and a second groove electrode (corresponding to an “excitation electrode” of the present disclosure) are formed on the groove portions of the arm portions, respectively. Moreover, a first side-surface electrode (corresponding to an “excitation electrode” of the present disclosure) is formed on both side surfaces of the right-side arm portion, and a second side-surface electrode (corresponding to an “excitation electrode” of the present disclosure) is formed on both side surfaces of the left-side arm portion. These respective electrodes are formed by a photolithography technique.

A specific method of forming the respective electrodes will be described.

First, a metal film is formed by sputtering or the like on a piezoelectric plate in which the outer shape of a piezoelectric vibrating reed is formed. Subsequently, a mask material formed of a photosensitive material is applied so as to overlap the metal film to thereby form a film of the mask material. After that, the mask material is exposed and developed to form a mask pattern for forming the respective electrodes. Finally, the metal film is etched through the mask pattern, whereby the metal film is patterned to form the respective electrodes.

The mask material is classified into two types of resist: one is a positive-type resist wherein an exposed portion is softened and removed, and the other is a negative-type resist wherein an exposed portion is hardened and left unremoved. As the positive-type resist, TMAH (tetramethylammonium hydroxide) or the like is widely used.

Development of a mask material using the positive-type resist is performed by immersing the mask material in a developing solution made from an alkaline solution such as aqueous sodium hydroxide, for example. Here, in general, a developing solution made from aqueous sodium hydroxide is known to have high viscosity. In order to form the respective electrodes with high accuracy, it is necessary to develop the mask material with high accuracy by allowing a developing solution having high viscosity to sufficiently permeate into the mask material.

However, since the tuning-fork type vibrating reed has a pair of vibrating arms of which the width is narrow, in particular, bubbles may remain in the root portion (see FIG. 1 of JP-A-2008-98747, corresponding to a “loin portion” of the present disclosure) of the pair of vibrating arms. The developing solution having high viscosity may not penetrate into the loin portion. As a result, the mask material in the root portion remains unremoved, and it may be difficult to form the mask pattern with high accuracy. Moreover, it may be difficult to remove the metal film with high accuracy by subsequent etching due to the remaining mask material, and electrode formation defects may occur. Specifically, the first side-surface electrode formed on the side surface of the right arm portion may be short-circuited to the second side-surface electrode formed on the side surface of the left arm portion.

Moreover, a method of decreasing the concentration of the developing solution to lower its viscosity so that the developing solution can easily permeate into the loin portion may be considered. However, with low concentrations of aqueous sodium hydroxide, insufficient development may be realized, so that the mask material is not completely removed but remains. Thus, it may be difficult to form the mask pattern with high accuracy. As a result, electrode formation defects may occur.

### SUMMARY OF THE INVENTION

Therefore, it is an object of the present invention to provide a method of manufacturing a piezoelectric vibrating reed capable of allowing a developing solution to sufficiently permeate into the loin portion to form a mask pattern with high accuracy to thereby prevent electrode formation defects. Another object of the present invention is to provide a piezoelectric vibrating reed manufactured by the manufacturing method, and a piezoelectric vibrator, an oscillator, an electronic device, and a radio-controlled timepiece each using the piezoelectric vibrating reed.

In order to attain the objects, according to an aspect of the present invention, there is provided a method of manufacturing a piezoelectric vibrating reed for forming electrodes on a surface of a piezoelectric plate, in which the outer shape of a piezoelectric vibrating reed is formed, using a photolithography technique, the piezoelectric vibrating reed including: a pair of vibrating arm portions arranged in a line; a base portion to which the pair of vibrating arm portions are connected, a loin portion formed in a connection portion between the vibrating arm portion and the base portion, and at least a first electrode and a second electrode which are formed on the side surfaces of the pair of vibrating arm portions facing each other with the loin portion disposed therebetween, wherein the electrode forming step of forming the respective electrodes includes: a metal film forming step of forming a metal film on the surface of the piezoelectric plate; a mask material application step of applying a mask material so as to overlap the metal film; an exposure step of exposing the mask material; a developing step of immersing the mask material in a developing solution to selectively remove the mask material to thereby form a mask pattern for forming the respective electrodes; and an etching step of performing etching of the metal film through the mask pattern to thereby form the respective electrodes, and wherein the electrode forming step includes an immersing step, between the exposure step and the developing step, of immersing the piezoelectric plate to which the mask material is applied in a first solution that is dissolvable in the developing solution and has lower viscosity than the developing solution.

According to the aspect of the present invention, the method includes an immersing step of immersing the piezoelectric plate in the first solution. Here, since the first solution has lower viscosity than the developing solution, the first solution can easily penetrate into the narrow loin portion. Moreover, since the immersing step is performed between the exposure step and the developing step, when the mask material is immersed in the developing solution in the developing step, the first solution and the developing solution adhering on the periphery of the loin portion from the immersing step are mixed with each other, and the developing solution penetrates into the loin portion. As a result, it is possible to remove the mask material in the loin portion with the developing solution and to prevent the mask material from remaining in the loin portion. As a result, it is possible to remove an electrode film in the loin portion in the etching step and to prevent the first electrode and the second electrode from being short-circuited. As above, it is possible to allow the developing solution to sufficiently penetrate into the loin portion to form the mask pattern with high accuracy to thereby prevent electrode formation defects.

Moreover, in the method of manufacturing the piezoelectric vibrating reed according to the above aspect of the present invention, the developing solution is preferably aqueous sodium hydroxide, and the first solution is preferably pure water.

The aqueous sodium hydroxide used as a positive-type resist developing solution has such a property that its viscosity is high and it easily mixes with pure water. According to the above aspect of the present invention, since the piezoelectric plate is immersed in pure water in the immersing step, when the mask material is immersed in aqueous sodium hydroxide which is the developing solution in the developing step, the pure water and the aqueous sodium hydroxide adhering on the periphery of the loin portion in the immersing step are mixed with each other, and the aqueous sodium hydroxide penetrates into the loin portion. Thus, even when the mask material is a positive-type resist and the mask material is immersed into the aqueous sodium hydroxide having high viscosity in the developing step, it is possible to allow the developing solution to sufficiently penetrate into the loin portion to form the mask pattern with high accuracy to thereby prevent electrode formation defects.

Moreover, the pure water is an inexpensive solution which is also used as a cleaning solution in the process of manufacturing the piezoelectric vibrating reed. Thus, by using pure water in the immersing step, it is possible to prevent electrode formation defects with a low cost.

According to another aspect of the present invention, there is provided a piezoelectric vibrating reed which is manufactured by the above-described manufacturing method.

According to the above aspect of the present invention, it is possible to provide a piezoelectric vibrating reed with no electrode formation defect.

According to a still another aspect of the present invention, there is provided a piezoelectric vibrator including the above-described piezoelectric vibrating reed.

According to the above aspect of the present invention, since the piezoelectric vibrator includes piezoelectric vibrating reeds with no electrode formation defects, it is possible to provide a piezoelectric vibrator with high reliability.

According to yet another aspect of the present invention, there is provided an oscillator in which the above-described piezoelectric vibrator is electrically connected to an integrated circuit as a vibrator.

According to yet another aspect of the present invention, there is provided an electronic device in which the above-described piezoelectric vibrator is electrically connected to a clock section.

According to yet another aspect of the present invention, there is provided a radio-controlled timepiece in which the above-described piezoelectric vibrator is electrically connected to a filter section.

According to the oscillator, the electronic device, and the radio-controlled timepiece according to the above aspects of the present invention, it is possible to provide an oscillator, an electronic device, and a radio-controlled timepiece with high reliability.

According to the aspects of the present invention, the method includes the immersing step of immersing the piezoelectric plate in the first solution. Here, since the first solution has lower viscosity than the developing solution, the first solution can easily penetrate into the narrow loin portion. Moreover, since the immersing step is performed between the exposure step and the developing step, when the mask material is immersed in the developing solution in the developing step, the first solution adhering to the periphery of the loin portion and the developing solution in the immersing step are mixed with each other, and the developing solution penetrates into the loin portion. As a result, it is possible to remove the mask material in the loin portion with the developing solution and to prevent the mask material from remaining in the loin portion. As a result, it is possible to remove an electrode film in the loin portion in the etching step and to prevent the first excitation electrode and the second excitation electrode from being short-circuited. As above, it is possible to allow the developing solution to sufficiently penetrate into the loin portion to form the mask pattern with high accuracy to thereby prevent electrode formation defects.

### BRIEF DESCRIPTION OF THE DRAWINGS

FIG. 1 is a plan view of a piezoelectric vibrating reed;

FIG. 2 is a sectional view taken along the line A-A in FIG. 1;

FIG. 3 is a perspective view of a loin portion;

FIG. 4 is a flowchart showing the process of manufacturing the piezoelectric vibrating reed;

FIG. 5 is a schematic view of a developing step in an electrode forming step according to the related art;

FIG. 6 is a diagram illustrating an immersing step;

FIG. 7 is a diagram illustrating a developing step;

FIG. 8 is a perspective view showing the external appearance of a piezoelectric vibrator.

FIG. 9 is a view showing the internal configuration of the piezoelectric vibrator and is also a plan view in a state where a lid substrate is removed;

FIG. 10 is a cross-sectional view of the piezoelectric vibrator taken along the line B-B in FIG. 9;

FIG. 11 is an exploded perspective view of the piezoelectric vibrator;

FIG. 12 is a view showing the configuration of an embodiment of an oscillator;

FIG. 13 is a view showing the configuration of an embodiment of an electronic device; and

FIG. 14 is a view showing the configuration of an embodiment of a radio-controlled timepiece.

### DETAILED DESCRIPTION OF THE PREFERRED EMBODIMENTS

### (Piezoelectric Vibrating Reed)

Hereinafter, a piezoelectric vibrating reed according to an embodiment of the present invention will be described with reference to the accompanying drawings.

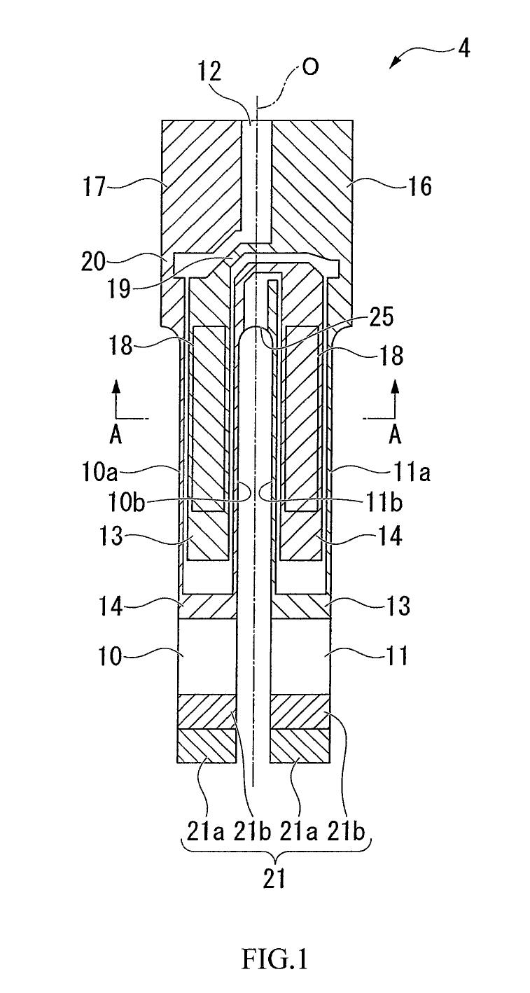

FIG. 1 is a plan view of a piezoelectric vibrating reed 4.

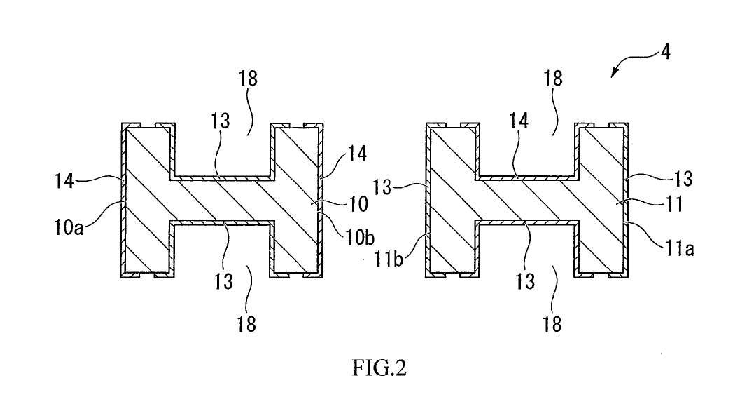

FIG. 2 is a sectional view taken along the line A-A in FIG. 1.

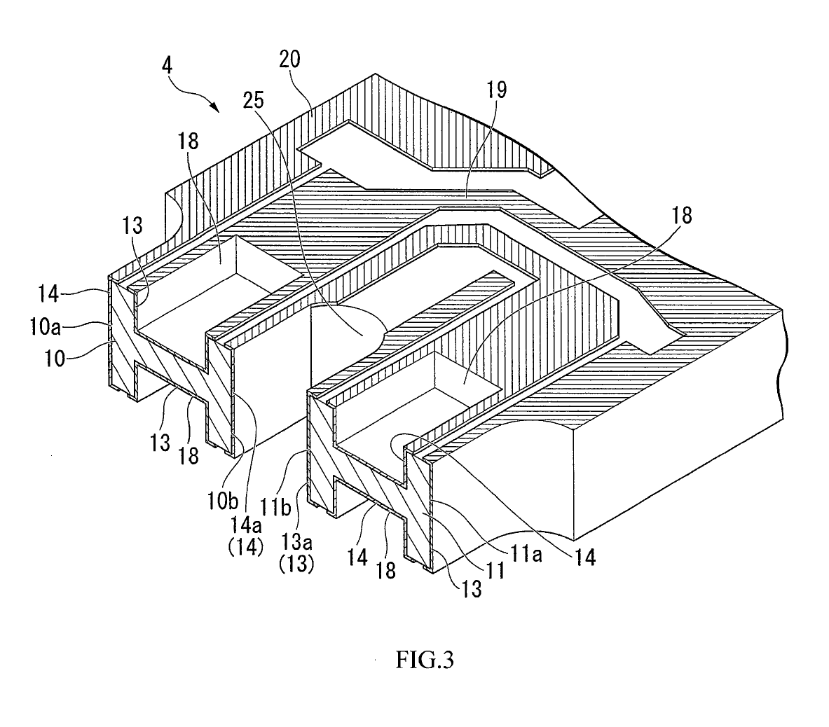

FIG. 3 is a perspective view of a loin portion 25.

As shown in FIG. 1, a piezoelectric vibrating reed 4 according to the present embodiment is a tuning-fork type vibrating reed which is made of a piezoelectric material such as crystal and is configured to vibrate when a predetermined voltage is applied thereto.

The piezoelectric vibrating reed 4 includes a pair of vibrating arm portions 10 and 11 arranged in a line, a base portion 12 to which the pair of vibrating arm portions 10 and 11 are connected, and a loin portion 25 that is formed in a connection portion between the pair of vibrating arm portions 10 and 11 and the base portion 12.

The pair of vibrating arm portions 10 and 11 extend along a central axis O and are disposed in parallel at the left and right sides of the central axis O. On both principal surfaces (top and bottom surfaces) of the vibrating arm portions 10 and 11, longitudinal grooves 18 are formed to have a fixed width along the longitudinal direction of the vibrating arm portions 10 and 11. The grooves 18 are formed so as to extend from the base end sides of the vibrating arm portions 10 and 11 to the vicinity of the intermediate portions of the vibrating arm portions 10 and 11. As a result, each of the pair of vibrating arm portions 10 and 11 has an H-shaped section as shown in FIG. 2.

As shown in FIG. 1, the base portion 12 is adjacent to the vibrating arm portions 10 and 11, and one set of ends of the vibrating arm portions 10 and 11 are connected to and supported by the base portion 12.

The loin portion 25 is formed in a region of the connection portion between the pair of vibrating arm portions 10 and 11 and the base portion 12 interposed by the pair of vibrating arm portions 10 and 11, and has an approximately U-shape in the plan view thereof.

The piezoelectric vibrating reed 4 includes excitation electrodes 13 and 14 (a first excitation electrode 13 and a second excitation electrode 14) formed in the vibrating arm portions 10 and 11, mount electrodes 16 and 17 formed in the base portion 12, and extraction electrodes 19 and 20 electrically connecting the excitation electrodes 13 and 14 and the mount electrodes 16 and 17 to each other.

The first excitation electrode 13 and the second excitation electrode 14 are formed on the principal surfaces of the pair of vibrating arm portions 10 and 11 using a single-layer conductive film of chromium, for example. The first excitation electrode 13 and the second excitation electrode 14 are electrodes that vibrate the pair of vibrating arm portions 10 and 11 at a predetermined resonance frequency in a direction of moving closer to or away from each other when a voltage is applied. The first excitation electrode 13 and the second excitation electrode 14 are formed on the outer surfaces of the pair of vibrating arm portions 10 and 11 by patterning in an electrically isolated state.

Specifically, as shown in FIG. 3, the first excitation electrode 13 is mainly formed inside the groove portion 18 of one vibrating arm portion 10 and on the outer side surface 11a of the other vibrating arm portion 11 and the inner side surface 11b of the other vibrating arm portion 11. The second excitation electrode 14 is mainly formed inside the groove portion 18 of the other vibrating arm portion 11 and on the outer side surface 10a of one vibrating arm portion 10 and the inner side surface 10b of one vibrating arm portion 10.

Here, a first excitation side-surface electrode 13a formed on the inner side surface 11b of the other vibrating arm portion 11 and a second excitation side-surface electrode 14a formed on the inner side surface 10b of one vibrating arm portion 10 face each other with the loin portion 25 disposed therebetween. The first excitation electrode 13 and the second excitation electrode 14 are formed by patterning in a state where no electrode is formed on the surface of the loin portion 25, and the excitation electrodes are electrically isolated from the loin portion 25.

As shown in FIG. 1, the first excitation electrode 13 and the second excitation electrode 14 are electrically connected to the mount electrodes 16 and 17 described later through the extraction electrodes 19 and 20, respectively, on both principal surfaces of the base portion 12. The extraction electrodes 19 and 20 are formed by a single-layer film of chromium which is the same material as the base layer of the mount electrodes 16 and 17. Therefore, it is possible to form the extraction electrodes 19 and 20 at the same time as the forming of the base layer of the mount electrodes 16 and 17. However, the present invention is not limited to this, the extraction electrodes 19 and 20 may be formed, for example, using nickel, aluminum, titanium, and the like.

A pair of mount electrodes 16 and 17 is formed on the outer side surface of the base portion 12. The mount electrodes 16 and 17 of the present embodiment are laminated films of chromium (Cr) and gold (Au), which are formed by forming a chromium (Cr) film having good adhesion with crystal as a base layer and then forming a thin gold (Au) film on the surface thereof as a finishing layer. However, the present invention is not limited to this, and the mount electrodes 16 and 17 may be formed by forming a chromium film and a nichrome film as a base layer and then forming a thin gold film on the surface thereof as a finishing layer.

In addition, a weight metal film 21 configured to include a rough adjustment film 21a and a fine adjustment film 21b for performing adjustment (frequency adjustment) so that the vibrating arm portions 10 and 11 vibrate within a predetermined frequency range and is formed at the distal ends of the vibrating arm portion 10 and 11. By performing frequency adjustment using the weight metal film 21, the frequency of the pair of the vibrating arm portions 10 and 11 can be set to fall within the nominal frequency range of the device.

### (Method of Manufacturing Piezoelectric Vibrating Reed)

Next, a method of manufacturing the piezoelectric vibrating reed 4 of the present invention will be described with reference to the flowchart.

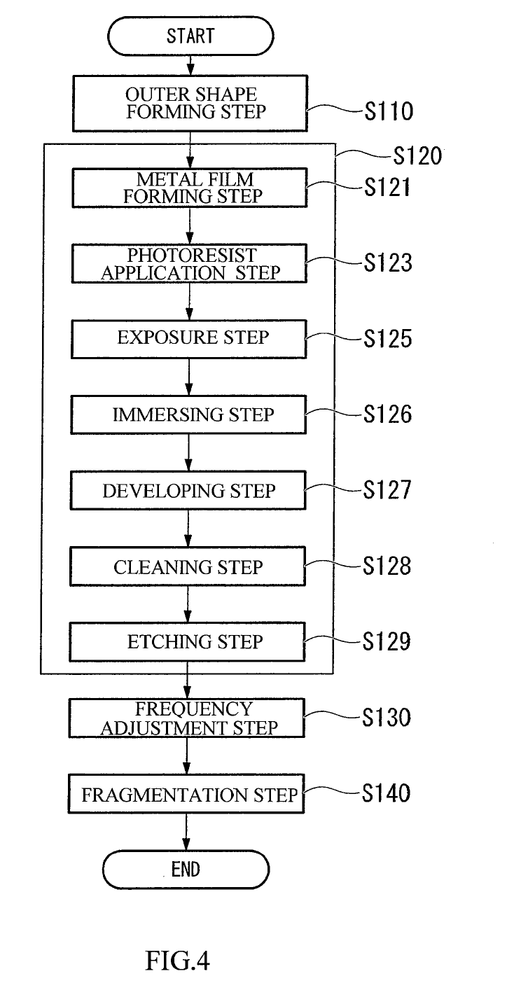

FIG. 4 is a flowchart showing the process of manufacturing the piezoelectric vibrating reed 4.

The process of manufacturing the piezoelectric vibrator 4 according to the present embodiment mainly includes an outer shape forming step S110 of forming a plurality of outer shapes of the piezoelectric vibrating reed 4, an electrode forming step S120 of forming the respective electrodes mainly on a crystal wafer, a frequency adjustment step S130 of adjusting a resonance frequency, and a fragmentation step S140 of cutting the plurality of piezoelectric vibrating reeds from one crystal wafer. The respective steps will be described in detail below.

### (Outer Shape Forming Step S110)

First, an outer shape forming step S110 of forming a plurality of outer shapes of the piezoelectric vibrating reed 4 (see FIG. 1) on a crystal wafer and then forming a recess serving as the groove portion 18 (see FIG. 1) of the piezoelectric vibrating reed 4 is performed. Specifically, a crystal wafer which has been polished and finished to a predetermined thickness with high accuracy is prepared. Subsequently, the crystal wafer is etched by a photolithography technique to form a plurality of outer shapes of the piezoelectric vibrating reed 4 on the crystal wafer and form a recess serving as the groove portion 18. In this way, the outer shape forming step S110 ends.

### (Electrode Forming Step S120)

Subsequently, the electrode forming step S120 of forming the respective electrodes of the excitation electrodes 13 and 14, the extraction electrodes 19 and 20, and the mount electrodes 16 and 17 (see FIG. 1) on the surface of the crystal wafer on which the outer shape of the piezoelectric vibrating reed 4 is formed is performed.

As shown in FIG. 4, the electrode forming step S120 includes: a metal film forming step S121 of forming a metal film on the surface of the crystal wafer; a photoresist application step S123 (mask material application step) of applying a photoresist (mask material) so as to overlap the metal film; an exposure step S125 of exposing the photoresist, an immersing step S126 of immersing the crystal wafer in pure water (first solution); a developing step S127 of selectively removing the photoresist to form a mask pattern; and an etching step S129 of performing etching of the metal film through the mask pattern to thereby form the respective electrodes.

### (Metal Film Forming Step S121)

In the electrode forming step S120, first the metal film forming step S121 of forming a metal film later serving as the excitation electrode on the crystal wafer is performed. In the present embodiment, a film of chromium having good adhesion to crystal is formed on the surface of the crystal wafer to a thickness of about several μm by a sputtering method, a vacuum deposition method, or the like. Furthermore, a thin film of gold is formed on the chromium film as a finishing layer. In addition, the excitation electrodes 13 and 14 and the extraction electrodes 19 and 20 shown in FIG. 1 are formed by a single-layer film of only chromium, and the mount electrodes 16 and 17 are formed by a laminated film of chromium and gold.

### (Photoresist Application Step S123)

Subsequently, the photoresist application step S123 of applying a photoresist so as to overlap the metal film is performed. As described above, although the photoresist is classified into a positive-type resist wherein an exposed portion is softened and removed and a negative-type resist wherein an exposed portion is left unremoved, in the present embodiment, the positive-type resist is applied. The photoresist is applied on the entire surface of the crystal wafer so as to overlap the metal film by a spray coating method, a spin coating method, or the like.

### (Exposure Step S125)

In the exposure step S125, a photomask having an opening is set in a state of facing the photoresist, and the photoresist is irradiated with an ultraviolet beam through the opening.

The opening of the photomask is formed in a region in which the photoresist is to be removed and is formed so as to correspond to a region in which the electrode film is to be removed in the etching step S129 described later. In other words, the opening of the photomask is formed so as to correspond to a region where the respective electrodes of the excitation electrodes 13 and 14, the extraction electrodes 19 and 20, and the mount electrodes 16 and 17 (see FIG. 1) are not formed. When the exposure is finished, the photomask is removed.

However, in the related art, after the exposure step S125 is performed, the developing step S127 of selectively removing the photoresist to form a mask pattern is performed.

FIG. 5 is a schematic view of the developing step S127 in the electrode forming step S120 of the related art. Although a plurality of piezoelectric vibrating reed outer shape portions 4a is formed on a crystal wafer 60, only one piezoelectric vibrating reed outer shape portion 4a is illustrated in FIG. 5 for better understanding.

As shown in FIG. 5, the developing step S127 is performed by immersing the crystal wafer 60 in a developing solution 51 stored in a tank (not shown). Here, in the present embodiment, since a positive-type resist is used for the photoresist 55, aqueous sodium hydroxide 51a is used as the developing solution 51. Since the aqueous sodium hydroxide 51a is generally a solution having high viscosity, when the crystal wafer 60 on which the photoresist 55 is applied is immersed in the aqueous sodium hydroxide 51a, the aqueous sodium hydroxide 51a slowly permeates in a space between the inner side surface 61a of one vibrating arm outer shape portion 61 of the crystal wafer 60 and the inner side surface 62a of the other vibrating arm outer shape portion 62.

Here, air which was present in the loin portion 25 from the atmosphere when the crystal wafer 60 was immersed in the aqueous sodium hydroxide 51a remains in the loin portion 25 as a bubble 68 in the aqueous sodium hydroxide 51a. The bubble 68 may prevent the aqueous sodium hydroxide 51a from penetrating up to the surface of the loin portion 25. As a result, the photoresist 55 on the surface of the loin portion 25 may remain unremoved, and it may be difficult to form the mask pattern with high accuracy.

Moreover, it may be difficult to remove the metal film with high accuracy in the subsequent etching step S129 due to the remaining photoresist 55, and electrode formation defects may occur. Specifically, the first excitation side-surface electrode 13a formed on the inner side surface 11b of the other vibrating arm portion 11 shown in FIG. 3 and the second excitation side-surface electrode 14a formed on the inner side surface 10b of one vibrating arm portion 10 may be short-circuited by the metal film remaining unetched.

Therefore, in order to form the mask pattern with high accuracy to prevent electrode formation defects, the immersing step S126 described below is performed between the exposure step S125 and the developing step S127.

### (Immersing Step S126)

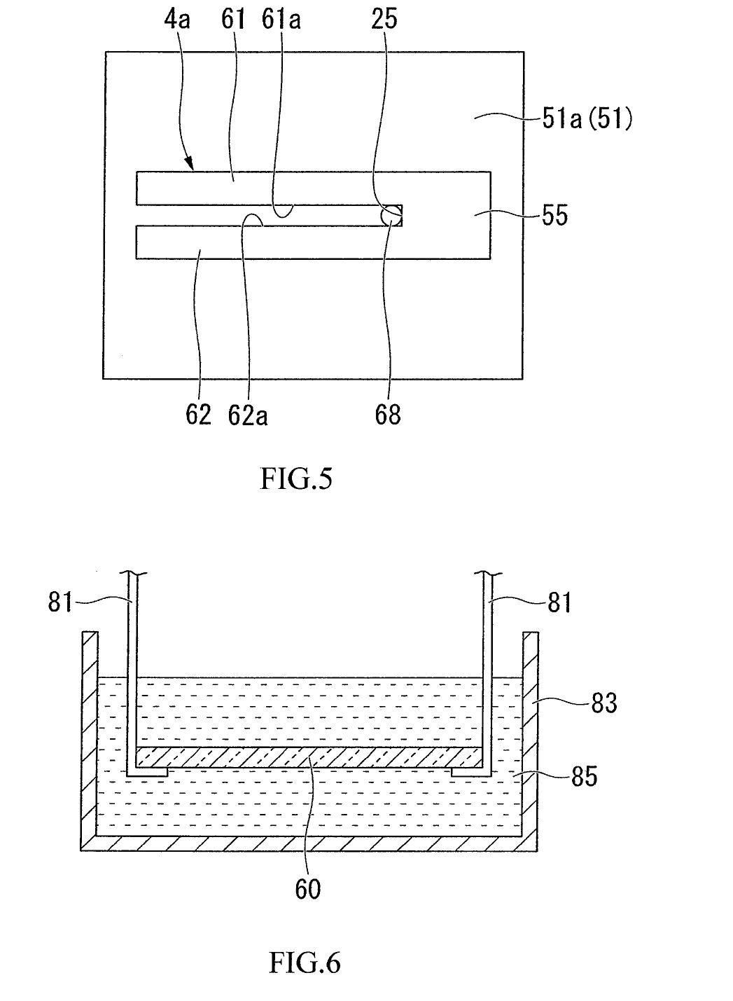

FIG. 6 is a diagram illustrating the immersing step S126.

Subsequently, as shown in FIG. 6, the immersing step S126 of immersing the crystal wafer 60 in pure water 85 is performed.

The reason for immersing the crystal wafer 60 in the pure water 85 in the immersing step S126 is because the pure water 85 is dissolvable in the aqueous sodium hydroxide 51a used in the developing step S127 and has lower viscosity than the aqueous sodium hydroxide 51a and can penetrate the narrow portions (for example, the loin portion 25, see FIG. 5) formed in the crystal wafer 60. Moreover, since the pure water 85 has lower surface tension than the aqueous sodium hydroxide 51a and has good soaking properties, the pure water 85 soaks, spreads, and adheres to the surface of the crystal wafer 60.

Due to the pure water 85 which penetrates into the loin portion 25 of the crystal wafer 60 to soak, spread on the surface of the crystal wafer 60, in the subsequent developing step S127, the aqueous sodium hydroxide 51a having low viscosity and the pure water 85 are mixed with each other, and it becomes easy for the aqueous sodium hydroxide 51a to penetrate into the loin portion 25.

In the immersing step S126, the crystal wafer 60 is immersed in the pure water 85 stored in the tank 83. Specifically, both ends of the crystal wafer 60 are grasped by a pair of arms 81, for example, and the crystal wafer 60 is conveyed into the pure water 85 of the tank 83. After that, the pair of arms 81 is operated in the front-back direction and the left-right direction with the crystal wafer 60 grasped by the pair of arms 81 so as to shake the crystal wafer 60 in the pure water 85. In this way, the pure water 85 can easily permeate into the loin portion 25 (see FIG. 5) of the crystal wafer 60.

After shaking the crystal wafer 60 for a predetermined period, the pair of arms 81 grasping the crystal wafer 60 is moved upward, whereby the crystal wafer 60 is taken out of the pure water 85 of the tank 83. After taking out the crystal wafer 60, the loin portion 25 and the periphery thereof are in a state where the pure water 85 has soaked, spread and is adhering to it.

### (Developing Step S127)

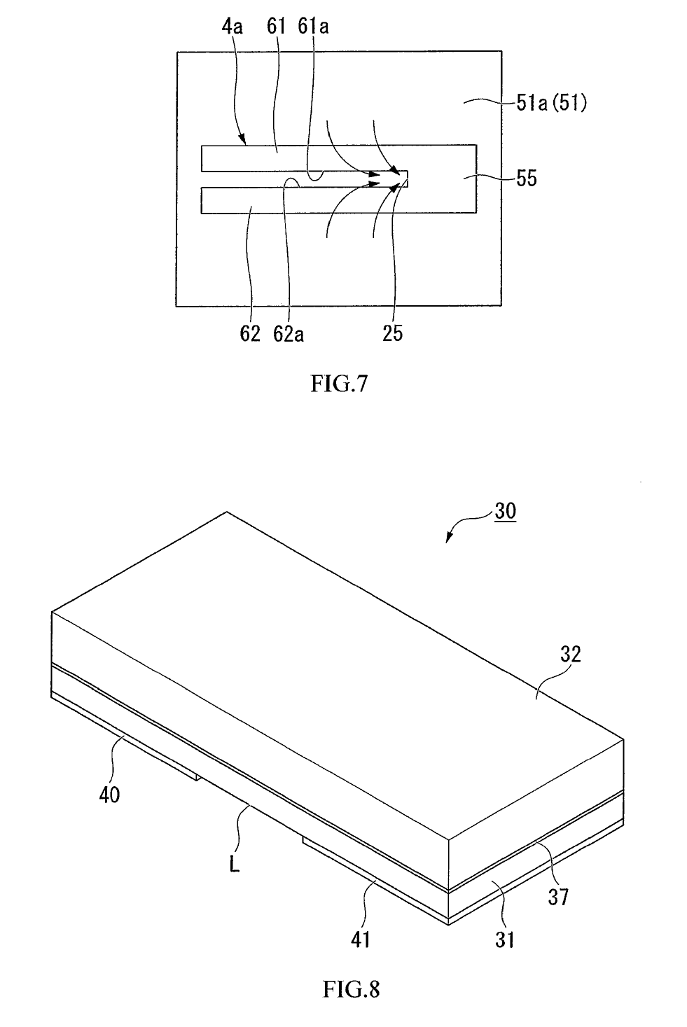

FIG. 7 is a diagram illustrating the developing step S127. In FIG. 7, only one piezoelectric vibrating reed outer shape portion 4a is illustrated for better understanding similarly to FIG. 5.

Subsequently, as shown in FIG. 7, the developing step S127 of immersing the crystal wafer 60 on which the photoresist 55 is applied in the developing solution 51 to selectively remove the photoresist 55 to thereby form a resist pattern (mask pattern) is performed.

Specifically, in the developing step S127, the photoresist corresponding to the region irradiated by an ultraviolet beam through the opening of the photomask, namely the region where the respective electrodes of the excitation electrodes 13 and 14, the extraction electrodes 19 and 20, and the mount electrodes 16 and 17 (see FIG. 1) are not formed is removed.

Here, by the immersing step S126, the pure water 85 still adheres on the loin portion 25 and the periphery thereof.

In this way, when the crystal wafer 60 is immersed in the aqueous sodium hydroxide 51a, the pure water 85 and the aqueous sodium hydroxide 51a are mixed with each other, the viscosity of the aqueous sodium hydroxide 51a decreases in a local area, and the aqueous sodium hydroxide 51a having low viscosity mixed with the pure water 85 permeates into the loin portion 25.

Moreover, once the aqueous sodium hydroxide 51a having low viscosity mixed with the pure water 85 permeates into the loin portion 25, the aqueous sodium hydroxide 51a having high viscosity (namely high concentration) can also subsequently permeate into the loin portion 25. In this way, it is possible to remove the photoresist corresponding to the region where the respective electrodes are not formed and to perform development reliably and form the resist pattern.

As above, in the developing step S127 of the present embodiment, the aqueous sodium hydroxide 51a permeates into such narrow regions as the loin portion 25 to remove the photoresist. Moreover, the resist pattern remains in the region where the respective electrodes of the excitation electrodes 13 and 14, the extraction electrodes 19 and 20, and the mount electrodes 16 and 17 of the piezoelectric vibrating reed 4 are formed.

### (Cleaning Step S128)

Subsequently, a cleaning step S128 of washing out the developing solution 51 (the aqueous sodium hydroxide 51a) remaining on the crystal wafer 60 from the developing step S127 is performed. In the cleaning step S128, in the same way as in immersing step S126, the crystal wafer 60 is immersed in the pure water 85 stored in a tank (not shown) and the crystal wafer 60 is shaken in the pure water 85, whereby the developing solution 51 remaining on the surface of the crystal wafer 60 is washed out.

Here, the tank 83 (see FIG. 6) used in the immersing step S126 described above and the tank (not shown) used in the cleaning step S128 communicate with each other, and the pure water 85 circulates between the respective tanks. That is, the pure water 85 used in the immersing step S126 is the same as the pure water 85 used in the cleaning step S128. Furthermore, any one of the tanks is configured as a jet flow tank so that the pure water 85 is continuously supplied to the tank. As above, by circulating the pure water 85 used in the cleaning step S128 so as to be used in the immersing step S126, the immersing step S126 is thereby realized at a low cost to prevent electrode formation defects.

### (Etching Step S129)

Subsequently, an etching step S129 of performing etching using the resist pattern as a mask to thereby form the respective electrodes is performed. In this step, the metal film which is mot masked by the resist pattern is selectively removed while leaving the metal film which is masked by the resist pattern. By the etching step S129, the excitation electrodes 13 and 14, the extraction electrodes 19 and 20, and the mount electrodes 16 and 17 of the piezoelectric vibrating reed 4 are formed (see FIG. 1).

Here, since the photoresist on the surface of the loin portion 25 is removed by the developing step S127 described above, the electrode film in the loin portion 25 is completely removed by the etching step S129. Therefore, as shown in FIG. 3, since no electrode film remains in the loin portion 25, the first excitation side-surface electrode 13a formed on the inner side surface 11b of the other vibrating arm portion 11 and the second excitation side-surface electrode 14a formed on the inner side surface 10b of one vibrating arm portion 10 can be prevented from being short-circuited. The electrode forming step S120 ends when the etching step S129 ends.

### (Frequency Adjustment Step S130)

Subsequently, as shown in FIG. 1, the weight metal film 21 (for example, silver or gold) configured to include the rough adjustment film 21a and the fine adjustment film 21b for frequency adjustment is formed at the distal ends of the pair of vibrating arm portions 10 and 11. Moreover a frequency adjustment step S130 of roughly adjusting the resonance frequency of all vibrating arm portions 10 and 11 formed on the crystal wafer 60 is performed. This is performed by changing the weight by irradiating the rough adjustment film 21a of the weight metal film 21 with a laser to evaporate a part of the rough adjustment film 21a. In addition, fine adjustment for adjusting the resonance frequency more accurately is performed in the state of a piezoelectric vibrator 30 (see FIG. 8). In this way, the frequency adjustment step S130 ends.

### (Fragmentation Step S140)

Finally, a fragmentation step S140 of cutting the connecting portion which connects the crystal wafer 60 and the piezoelectric vibrating reeds 4 to thereby separate the plurality of piezoelectric vibrating reeds 4 from the crystal wafer 60 to obtain fragmented pieces is performed. As a result, the plurality of tuning-fork type piezoelectric vibrating reeds 4 can be simultaneously manufactured from one crystal wafer 60. At this point, the process of manufacturing the piezoelectric vibrating reed 4 ends, and a plurality of piezoelectric vibrating reeds 4 can be obtained.

### (Effects of Present Embodiment)

According to the embodiment of the present invention, the manufacturing method includes the immersing step S126 of immersing the crystal wafer in pure water. Here, the pure water 85 has lower viscosity than the aqueous sodium hydroxide 51a which is the developing solution 51, the pure water 85 can easily permeate into the narrow loin portion 25. Moreover, since the immersing step S126 is performed between the exposure step S125 and the developing step S127, when the photoresist is immersed in the aqueous sodium hydroxide in the developing step S127, the pure water 85 adhering on the periphery of the loin portion 25 in the immersing step S126 and the aqueous sodium hydroxide 51a are mixed with each other, and the aqueous sodium hydroxide permeates into the loin portion 25. As a result, it is possible to remove the photoresist in the loin portion 25 with the aqueous sodium hydroxide 51a and to prevent the photoresist from remaining in the loin portion 25. Thus, it is possible to remove the electrode film in the loin portion 25 in the etching step S129 and to prevent the first excitation side-surface electrode 13a and the second excitation side-surface electrode 14a from being short-circuited. In this way, it is possible to allow the aqueous sodium hydroxide 51a to sufficiently permeate into the loin portion 25 to form the mask pattern with high accuracy to thereby prevent electrode formation defects.

### (Piezoelectric Vibrator)

Next, a piezoelectric vibrator using the piezoelectric vibrating reed 4 according to the present embodiment will be described.

FIG. 8 is a perspective view showing the external appearance of a piezoelectric vibrator 30.

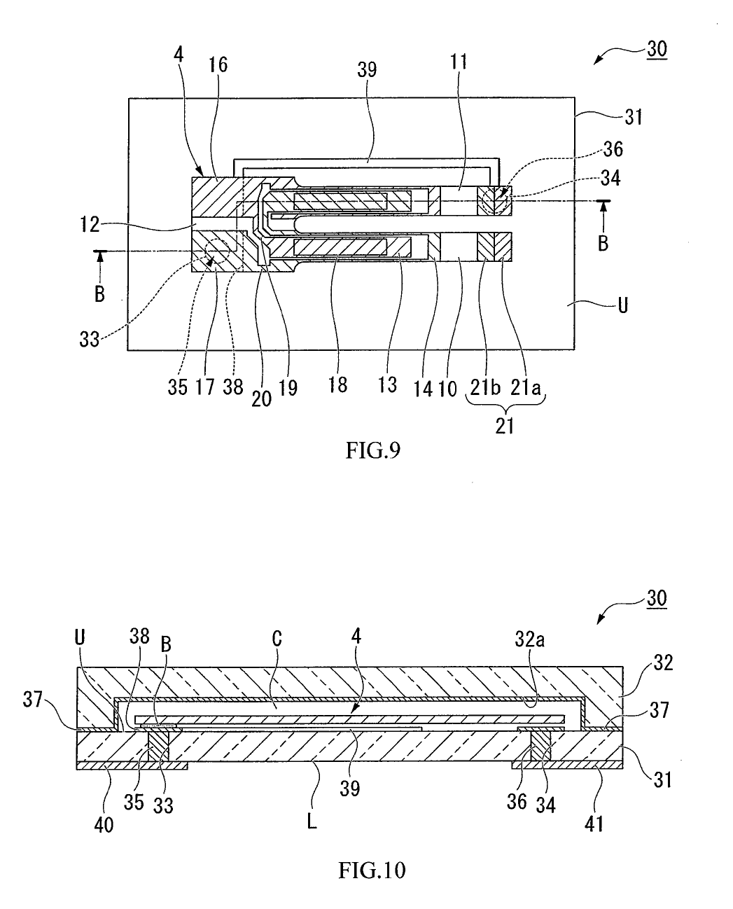

FIG. 9 is a view showing the internal configuration of the piezoelectric vibrator 30 and is also a plan view in a state where a lid substrate 32 is removed.

FIG. 10 is a cross-sectional view taken along the line B-B in FIG. 9.

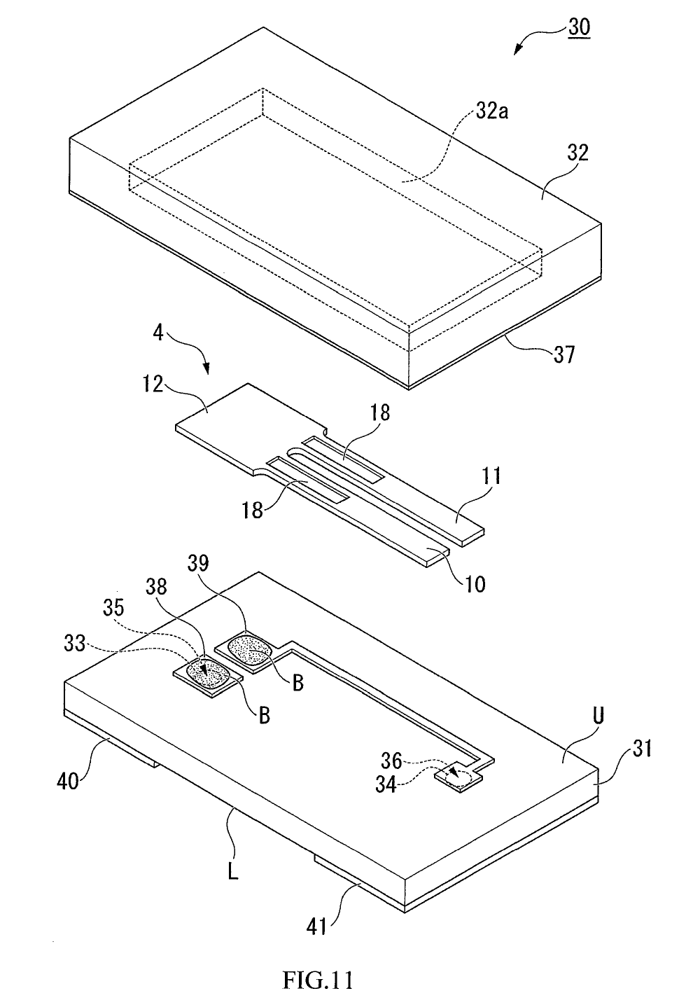

FIG. 11 is an exploded perspective view of the piezoelectric vibrator 30 shown in FIG. 8.

Furthermore, the bonding surface of a base substrate 31 bonded to the lid substrate 32 will be called first surface U, and the outer surface of the base substrate 31 will be called second surface L. In FIG. 11, for better understanding of the drawings, the excitation electrodes 13 and 14, the extraction electrodes 19 and 20, the mount electrodes 16 and 17, and the weight metal film 21 are not illustrated.

As shown in FIG. 8, a piezoelectric vibrator 30 according to the present embodiment is a surface mounted device-type piezoelectric vibrator 30 which includes a package, in which a base substrate 31 and a lid substrate 32 are anodically bonded to each other with a bonding film 37 disposed therebetween, and a piezoelectric vibrating reed 4 which is accommodated in a cavity C of the package as shown in FIG. 10.

The base substrate 31 and the lid substrate 32 are substrates that can be anodically bonded and that are made of a glass material, for example, soda-lime glass, and are formed in a plate-like form. On the bonding surface side of the lid substrate 32 to be bonded to the base substrate 31, a cavity recess 32a is formed in which the piezoelectric vibrating reed 4 is accommodated.

A bonding film 37 for anodic bonding is formed on the entire surface on the bonding surface side of the lid substrate 32 to be bonded to the base substrate 31. That is, the bonding film 37 is formed in a frame region at the periphery of the cavity recess 32a in addition to the entire inner surface of the cavity recess 32a. Although the bonding film 37 of the present embodiment is made of a silicon film, the bonding film 37 may be made of aluminum (Al) or Cr. As will be described later, the bonding film 37 and the base substrate 31 are anodically bonded, whereby the cavity C is vacuum-sealed.

As shown in FIG. 10, the piezoelectric vibrator 30 includes penetration electrodes 35 and 36 which penetrate through the base substrate 31 in the thickness direction thereof so that the inside of the cavity C is electrically connected to the outside of the piezoelectric vibrator 30. The penetration electrodes 35 and 36 are disposed in penetration holes 33 and 34 which penetrate through the base substrate 31.

The cross section in the direction perpendicular to the central axis of the penetration holes 33 and 34 has an approximately circular shape. Moreover, the penetration holes 33 and 34 are formed so that the piezoelectric vibrator 30 is received in the cavity C when the piezoelectric vibrator 30 is formed. More specifically, the penetration holes 33 and 34 are formed such that one penetration hole 33 is positioned on the base end side of the piezoelectric vibrating reed 4, and the other penetration hole 34 is formed on the distal end sides of the vibrating arm portions 10 and 11.

The penetration electrodes 35 and 36 are formed, for example, by inserting a metal pin (not shown) into the penetration holes 33 and 34, filling a glass frit between the penetration holes 33 and 34 and the metal pin, and baking the glass frit. In this way, since it is possible to completely block the penetration holes 33 and 34 by the metal pin and the glass frit, the penetration electrodes 35 and 36 serve to make lead-out electrodes 38 and 39 and external electrodes 40 and 41 described later electrically connected to each other while maintaining the airtightness in the cavity C.

As shown in FIG. 11, a pair of lead-out electrodes 38 and 39 is patterned on the first surface U side of the base substrate 31. One lead-out electrode 38 among the pair of lead-out electrodes 38 and 39 is formed so as to be disposed right above one penetration electrode 35. Moreover, the other lead-out electrode 39 is formed so as to be disposed right above the other penetration electrode 36 after being led out from a position next to the lead-out electrode 38 and around the distal end sides of the vibrating arm portions 10 and 11.

Moreover, tapered bumps B made of gold or the like are formed on the pair of lead-out electrodes 38 and 39, and the pair of mount electrodes 16 and 17 (see FIG. 9) of the piezoelectric vibrating reed 4 are realized on the lead-out electrodes 38 and 39 using the bumps B. In this way, as shown in FIG. 9, one mount electrode 16 of the piezoelectric vibrating reed 4 is electrically connected to the other penetration electrode 36 through the other lead-out electrode 39, and the other mount electrode 17 is electrically connected to one penetration electrode 35 through one lead-out electrode 38.

Moreover, a pair of external electrodes 40 and 41 is formed on the second surface L of the base substrate 31. The pair of external electrodes 40 and 41 are formed at both ends in the longitudinal direction (the left-right direction in FIG. 10) of the base substrate 31 and are electrically connected to the pair of penetration electrodes 35 and 36, respectively.

When the piezoelectric vibrator 30 configured in this manner is operated, a predetermined driving voltage is applied to the external electrodes 40 and 41 formed on the base substrate 31. In this way, since a voltage can be applied to the first excitation electrode 13 and the second excitation electrode 14 (see FIG. 1) of the piezoelectric vibrating reed 4, it is possible to vibrate the pair of vibrating arm portions 10 and 11 at a predetermined frequency in a direction of moving closer to and further away from each other. By using this vibration of the pair of vibrating arm portions 10 and 11, the piezoelectric vibrator 30 can be used as a time source, the timing source of a control signal, a reference signal source, and the like.

### (Oscillator)

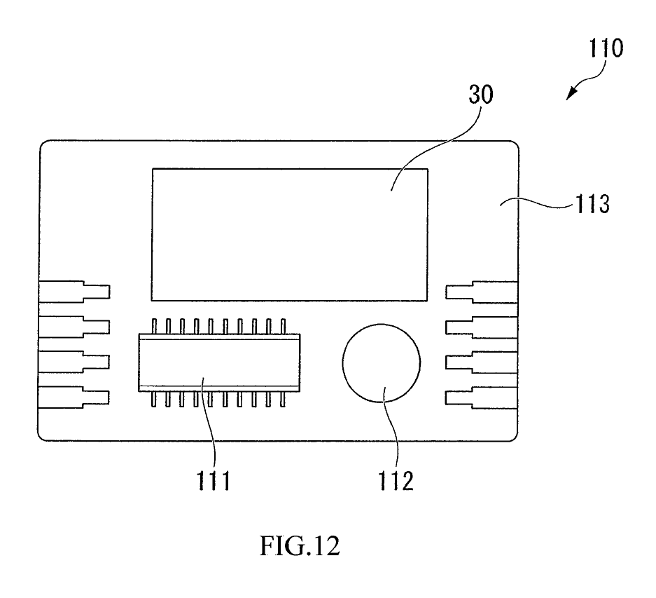

Next, an oscillator according to another embodiment of the present invention will be described with reference to FIG. 12.

In an oscillator 110 according to the present embodiment, the piezoelectric vibrator 30 is used as a vibrator electrically connected to an integrated circuit 111, as shown in FIG. 12. The oscillator 110 includes a substrate 113 on which an electronic component 112, such as a capacitor, is mounted. The integrated circuit 111 for an oscillator is mounted on the substrate 113, and a piezoelectric vibrating reed of the piezoelectric vibrator 30 is mounted near the integrated circuit 111. The electronic component 112, the integrated circuit 111, and the piezoelectric vibrator 30 are electrically connected to each other by a wiring pattern (not shown). In addition, each of the constituent components is molded with a resin (not shown).

In the oscillator 110 configured as described above, when a voltage is applied to the piezoelectric vibrator 30, the piezoelectric vibrating reed in the piezoelectric vibrator 30 vibrates. This vibration is converted into an electrical signal due to the piezoelectric property of the piezoelectric vibrating reed and is then input to the integrated circuit 111 as the electrical signal. The input electrical signal is subjected to various kinds of processing by the integrated circuit 111 and is then output as a frequency signal. In this way, the piezoelectric vibrator 30 functions as an oscillator.

Moreover, by selectively setting the configuration of the integrated circuit 111, for example, an RTC (Real Time Clock) module, according to demand, it is possible to add a function of controlling the operation date or time of the corresponding device or an external device or of providing the time or calendar in addition to a single functional oscillator for a clock.

According to the oscillator 110 of the present embodiment, since the oscillator 110 includes the highly reliable piezoelectric vibrator 30 including the piezoelectric vibrating reed 4 with no electrode formation defect, it is possible to provide the oscillator 110 which has good performance.

### (Electronic Device)

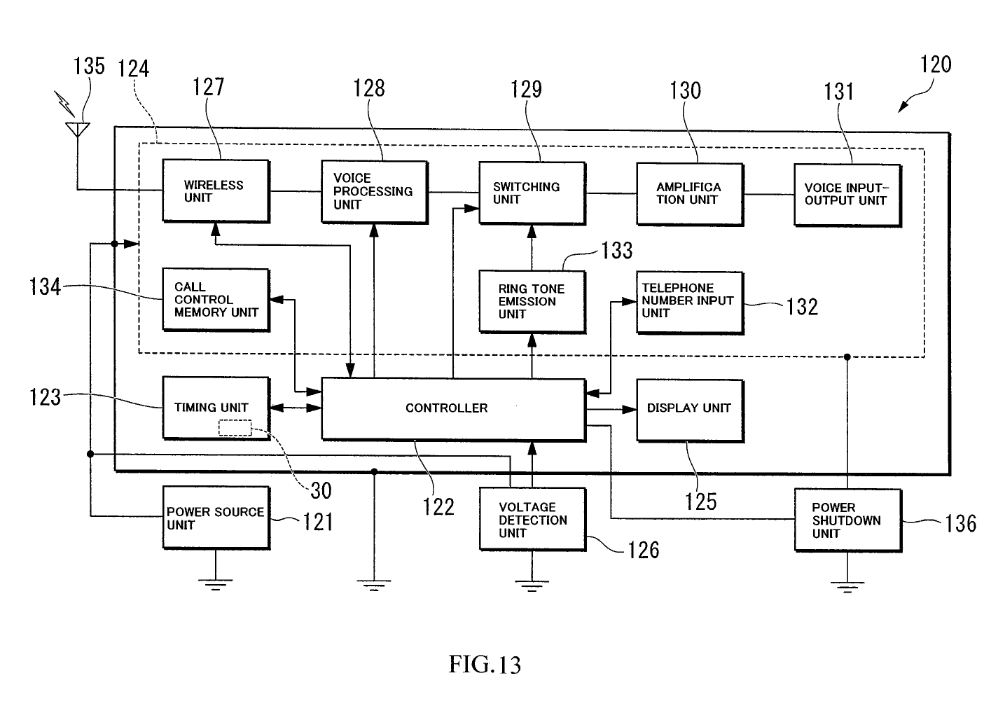

Next, an electronic device according to another embodiment of the present invention will be described with reference to FIG. 13. In addition, a mobile information device 120 including the piezoelectric vibrator 30 will be described as an example of an electronic device.

The mobile information device 120 according to the present embodiment is represented by a mobile phone, for example, and has been developed and improved from a wristwatch in the related art. The mobile information device 120 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the mobile information device 120 is very small and light compared with a mobile phone in the related art.

Next, the configuration of the mobile information device 120 according to the present embodiment will be described. As shown in FIG. 13, the mobile information device 120 includes the piezoelectric vibrator 30 and a power supply section 121 for supplying power. The power supply section 121 is formed of a lithium secondary battery, for example. A control section 122 which performs various kinds of control, a clock section 123 which performs counting of time and the like, a communication section 124 which performs communication with the outside, a display section 125 which displays various kinds of information, and a voltage detecting section 126 which detects the voltage of each functional section are connected in parallel to the power supply section 121. In addition, the power supply section 121 supplies power to each functional section.

The control section 122 controls an operation of the entire system. For example, the control section 122 controls each functional section to transmit or receive the audio data or to measure and display a current time. In addition, the control section 122 includes a ROM in which a program is written in advance, a CPU which reads and executes a program written in the ROM, a RAM used as a work area of the CPU, and the like.

The clock section 123 includes an integrated circuit, which has an oscillation circuit, a register circuit, a counter circuit, and an interface circuit therein, and the piezoelectric vibrator 30. When a voltage is applied to the piezoelectric vibrator 30, the piezoelectric vibrating reed vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 122 through the interface circuit, and current time, current date, calendar information, and the like are displayed on the display section 125.

The communication section 124 has the same function as a mobile phone in the related art, and includes a wireless section 127, an audio processing section 128, a switching section 129, an amplifier section 130, an audio input/output section 131, a telephone number input section 132, a ring tone generating section 133, and a call control memory section 134.

The wireless section 127 transmits/receives various kinds of data, such as audio data, to/from the base station through an antenna 135. The audio processing section 128 encodes and decodes an audio signal input from the wireless section 127 or the amplifier section 130. The amplifier section 130 amplifies a signal input from the audio processing section 128 or the audio input/output section 131 up to a predetermined level. The audio input/output section 131 is formed by a speaker, a microphone, and the like, and amplifies a ring tone or incoming sound or collects the sound.

In addition, the ring tone generating section 133 generates a ring tone in response to a call from the base station. The switching section 129 switches the amplifier section 130, which is connected to the audio processing section 128, to the ring tone generating section 133 only when a call arrives, so that the ring tone generated in the ring tone generating section 133 is output to the audio input/output section 131 through the amplifier section 130.

In addition, the call control memory section 134 stores a program related to incoming and outgoing call control for communications. Moreover, the telephone number input section 132 includes, for example, numeric keys from 0 to 9 and other keys. The user inputs a telephone number of a communication destination by pressing these numeric keys and the like.

The voltage detecting section 126 detects a voltage drop when a voltage, which is applied from the power supply section 121 to each functional section, such as the control section 122, drops below the predetermined value, and notifies the control section 122 of the detection of the voltage drop. In this case, the predetermined voltage value is a value which is set beforehand as the lowest voltage necessary to operate the communication section 124 stably. For example, it is about 3 V. When the voltage drop is notified from the voltage detecting section 126, the control section 122 disables the operation of the wireless section 127, the audio processing section 128, the switching section 129, and the ring tone generating section 133. In particular, the operation of the wireless section 127 that consumes a large amount of power should be necessarily stopped. In addition, a message informing the user that the communication section 124 is not available due to insufficient battery power is displayed on the display section 125.

That is, it is possible to disable the operation of the communication section 124 and display the notice on the display section 125 by the voltage detection section 126 and the control section 122. This message may be a character message. Or as a more intuitive indication, a cross mark (X) may be displayed on a telephone icon displayed at the top of the display screen of the display section 125.

In addition, the function of the communication section 124 can be more reliably stopped by providing a power shutdown section 136 capable of selectively shutting down the power to a section related to the function of the communication section 124.

According to the mobile information device 120 of the present embodiment, since the mobile information device 120 includes the highly reliable piezoelectric vibrator 30 including the piezoelectric vibrating reed 4 with no electrode formation defect, it is possible to provide the mobile information device 120 which has good performance.

### (Radio-Controlled Timepiece)

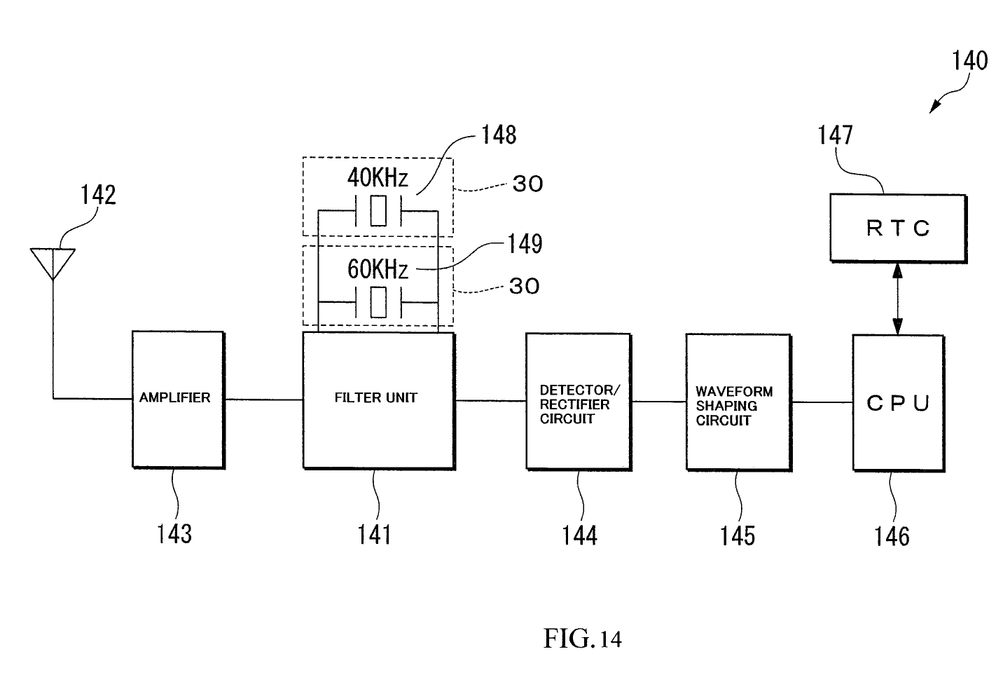

Next, a radio-controlled timepiece according to yet another embodiment of the present invention will be described with reference to FIG. 14.

As shown in FIG. 14, a radio-controlled timepiece 140 according to the present embodiment includes the piezoelectric vibrators 30 electrically connected to a filter section 141. The radio-controlled timepiece 140 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionosphere and the land surface, and therefore has a propagation range wide enough to cover the entire area of Japan through the two transmission centers.

Hereinafter, the functional configuration of the radio-controlled timepiece 140 will be described in detail.

An antenna 142 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 143 and is then filtered and synchronized by the filter section 141 having the plurality of piezoelectric vibrators 30.

In the present embodiment, the piezoelectric vibrators 30 include crystal vibrator sections 148 and 149 having resonance frequencies of 40 kHz and 60 kHz, respectively, which are the same frequencies as the carrier frequency.

In addition, the filtered signal with a predetermined frequency is detected and demodulated by a detection and rectification circuit 144.

Then, the time code is extracted by a waveform shaping circuit 145 and counted by the CPU 146. The CPU 146 reads the information including the current year, the total number of days, the day of the week, the time, and the like. The read information is reflected on an RTC 148, and the correct time information is displayed.

Because the carrier wave is 40 kHz or 60 kHz, a vibrator having the tuning fork structure described above is suitable for the crystal vibrator sections 148 and 149.

Moreover, although the above explanation has been given for the case in Japan, the frequency of a long standard wave is different in other countries. For example, a standard wave of 77.5 kHz is used in Germany. Therefore, when the radio-controlled timepiece 140 which is also operable in other countries is assembled in a portable device, the piezoelectric vibrator 30 corresponding to frequencies different from the frequencies used in Japan is necessary.

According to the radio-controlled timepiece 140 of the present embodiment, since the radio-controlled timepiece 140 includes the highly reliable piezoelectric vibrator 30 including the piezoelectric vibrating reed 4 with no electrode formation defect, it is possible to provide the radio-controlled timepiece 140 which has good performance.

In addition, the present invention is not limited to the embodiments described above.

In the present embodiment, the present invention has been described by way of an example in which the developing solution 51 permeates into the loin portion 25 of the tuning-fork type piezoelectric vibrating reed 4. However, the present invention is not limited to a case where the developing solution 51 permeates into the loin portion 25 of the tuning-fork type piezoelectric vibrating reed 4 but can be applied to when the developing solution 51 permeates into a narrow portion of a piezoelectric vibrating reed having another shape. In this case, the same effects as the above embodiment can be obtained.

In the present embodiment, although the aqueous sodium hydroxide 51a has been used as the developing solution 51, and the pure water 85 has been used as the first solution in the immersing step S126, the developing solution 51 is not limited to the aqueous sodium hydroxide 51a, and the first solution is not limited to the pure water 85.

In the present embodiment, although the method of manufacturing the piezoelectric vibrating reed 4 has been applied to the piezoelectric vibrating reed 4 mounted on the surface mounted device-type piezoelectric vibrator 30, the present invention is not limited to this. For example, the method of manufacturing the piezoelectric vibrating reed of the present invention may be applied to a piezoelectric vibrating reed mounted on a cylinder package-type piezoelectric vibrating reed.

What is claimed is:

1. A method of manufacturing a piezoelectric vibrating reed including forming electrodes on a surface of a piezoelectric plate, in which the outer shape of a piezoelectric vibrating reed is formed using a photolithography technique, the piezoelectric vibrating reed including:
a pair of vibrating arm portions arranged in a line;
a base portion to which the pair of vibrating arm portions are connected, a loin portion in a connection portion between the vibrating arm portions and the base portion, and at least a first electrode and a second electrode on the side surfaces of the pair of vibrating arm portions and facing each other with the loin portion disposed therebetween,
wherein forming the first and second electrodes comprises:
forming a metal film on the surface of the piezoelectric plate;
applying a mask material so as to overlap the metal film;
exposing the mask material;
immersing the mask material in a developing solution to selectively remove the mask material and thereby form a mask pattern for forming the respective electrodes; and
etching of the metal film through the mask pattern to thereby form the respective electrodes,
wherein the method further includes, between exposing the mask material and immersing the mask material in the developing step, immersing the piezoelectric plate to which the mask material is subjected to a first solution that is soluble in the developing solution and has lower viscosity than the developing solution.

2. The method according to claim 1, wherein immersing the mask material in a developing solution further comprises adhering a mixture of the first solution and the developing solution to a periphery of the loin portion, such that the developing solution penetrates into the loin portion and removes the mask material from the loin portion.

3. The method of manufacturing the piezoelectric vibrating reed according to claim 1, wherein the developing solution comprises concentrated aqueous sodium hydroxide, and the first solution comprises water.

4. The method of manufacturing the piezoelectric vibrating reed according to claim 3, wherein the aqueous sodium hydroxide comprises a positive-type resist developing solution having a high viscosity and is soluble in water.

5. The method of manufacturing the piezoelectric vibrating reed according to claim 3, wherein the water comprises substantially pure water.

6. The method of manufacturing the piezoelectric vibrating reed according to claim 1, wherein the mask material comprises a positive-type resist.

7. A piezoelectric vibrating reed manufactured by the method according to claim 1.

8. A piezoelectric vibrator including the piezoelectric vibrating reed according to claim 7.

9. An oscillator including the piezoelectric vibrator according to claim 8 electrically connected to an integrated circuit as a vibrator.

10. An electronic device including the piezoelectric vibrator according to claim 8 electrically connected to a clock section.

11. A radio-controlled timepiece including the piezoelectric vibrator according to claim 8 electrically connected to a filter section.

12. A method of manufacturing a piezoelectric vibrating reed including forming electrodes on a surface of a piezoelectric plate, the method comprising:
forming a metal film on the surface of the piezoelectric plate;
applying a mask material on the metal film;
exposing the mask material;
immersing the piezoelectric plate in a liquid and forming a low-viscosity film on a surface of the mask material;
developing the mask material in a developing solution to selectively remove the mask material and thereby form a mask pattern on the electrodes,
wherein the low-viscosity film effectively lowers the viscosity of the developing solution and promotes the spread of the developing solution over the surface of the mask material; and
etching of the metal film through the mask pattern to thereby form the respective electrodes.

13. The method of manufacturing the piezoelectric vibrating reed according to claim 12, wherein forming a metal film on the surface of the piezoelectric plate comprises:
forming a pair of vibrating arm portions arranged in a line, the vibrating arm portions having a base portion to which the pair of vibrating arm portions are connected, and a narrow region or loin portion in a connection region between the vibrating arm portions and the base portion; and
forming at least a first electrode and a second electrode on the side surfaces of the pair of vibrating arm portions, where the first and second electrodes face each other with the loin portion disposed therebetween.

14. The method of manufacturing the piezoelectric vibrating reed according to claim 12, wherein during developing the mask material, the developing solution mixes with the liquid and permeates the narrow region of loin portion between the vibrating arm portions.

15. The method of manufacturing the piezoelectric vibrating reed according to claim 12, wherein the developing solution comprises a concentrated aqueous sodium hydroxide, and the liquid comprises water.

16. The method of manufacturing the piezoelectric vibrating reed according to claim 12 further comprising, after developing the mask material and prior to etching of the metal film, cleaning the mask pattern by immersing the piezoelectric plate in the liquid.

17. The method of manufacturing the piezoelectric vibrating reed according to claim 16 further comprising providing first and second baths in fluid communication, and wherein immersing the piezoelectric plate in a liquid comprises immersing the piezoelectric plate in the first bath and cleaning the mask pattern comprises immersing the piezoelectric plate in the second bath.
